(19) United States
(12) Patent Application Publication
(10) Pub. No.: US 2026/0057916 A1
(43) Pub. Date: Feb. 26, 2026

(54) MEMORY DEVICE AND OPERATING METHOD OF THE SAME

(71) Applicant: SK hynix Inc., Icheon-si (KR)

(72) Inventors: Hyun Soo Kim, Icheon-si (KR); Gap Sok DO, Icheon-si (KR)

(21) Appl. No.: 19/045,042

(22) Filed: Feb. 4, 2025

(30) Foreign Application Priority Data
Aug. 23, 2024 (KR) 10-2024-0113730

(51) Int. Cl. G11C 7/04; G11C 7/10

(52) U.S. Cl. CPC G11C 7/04; G11C 7/1066; G11C 7/1069; G11C 7/1096

(57) ABSTRACT

A memory device may include a memory cell array including a plurality of memory cells, an off-temperature determination circuit configured to generate an off-temperature code based on a level of a threshold voltage of at least one memory cell included in a specific region of the memory cell array, a control circuit configured to generate a voltage control signal based on the off-temperature code, and a read voltage generation circuit configured to provide a read voltage to the memory cell array based on the voltage control signal.

### CROSS-REFERENCE TO RELATED APPLICATION

This application claims priority under 35 U.S.C. § 119(a) to Korean Patent Application No. 10-2024-0113730, filed in the Korean Intellectual Property Office on Aug. 23, 2024, the entire contents of which are incorporated herein by reference.

### BACKGROUND

### 1. Technical Field

Embodiments relate to an integrated circuit technology and to a memory device and an operating method of the same.

### 2. Related Art

Recently, as an electronic device is reduced in size, has lower power consumption and higher performance, and is diversified, a memory device capable of storing information is required for various electronic devices, such as computers and portable communication devices.

Research is carried out on a memory device that selects its operating method suitable for a current temperature by checking the temperature while being driven because the memory device is sensitive to a temperature. In particular, a memory device being in a power off state has a high probability that a malfunction may occur when the memory device switches from the power off state to a power on state because it is unknown what temperature the memory device went through.

### SUMMARY

In an embodiment, a memory device may include a memory cell array including a plurality of memory cells, an off-temperature determination circuit configured to generate an off-temperature code based on the level of a threshold voltage of at least one memory cell included in a specific region of the memory cell array, a control circuit configured to generate a voltage control signal based on the off-temperature code, and a read voltage generation circuit configured to provide a read voltage to the memory cell array based on the voltage control signal.

In an embodiment, an operating method of a memory device may include generating an off-temperature code based on a characteristic of at least one memory cell in a specific region of the memory cell array, the off-temperature code indicating a temperature change occurred in the memory device in a power off state; and generating a read voltage based on the off-temperature code to provide the read voltage to the memory cell array.

### BRIEF DESCRIPTION OF THE DRAWINGS

FIG. 1 is a diagram for describing a construction of a memory device according to an embodiment of the present disclosure.

FIGS. 2 and 3 are diagrams for describing memory cells of the memory device according to an embodiment of the present disclosure.

FIG. 4 is a diagram for describing a construction of an off-temperature determination circuit according to an embodiment of the present disclosure.

FIG. 5 is a diagram for describing an operation of the off-temperature determination circuit according to an embodiment of the present disclosure.

FIG. 6 is a graph for describing an operation of the memory device according to an embodiment of the present disclosure.

FIG. 7 is a flowchart for describing an operation of the memory device according to an embodiment of the present disclosure.

### DETAILED DESCRIPTION

Hereinafter, some embodiments of the present disclosure are described with reference to the accompanying drawings.

Embodiments of the present disclosure provide a memory device capable of storing a temperature change even in a power off state and an operating method of the same.

A normal operation can be performed even in a temperature change in the power off state.

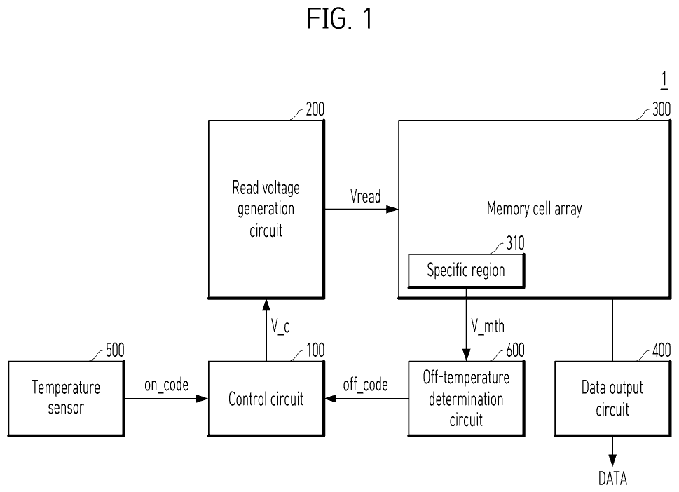

FIG. 1 is a diagram for describing a construction of a memory device 1 according to an embodiment of the present disclosure.

Referring to FIG. 1, the memory device 1 may include a control circuit 100, a read voltage generation circuit 200, a memory cell array 300, a data output circuit 400, a temperature sensor 500, and an off-temperature determination circuit 600.

The control circuit 100 may control internal circuits of the memory device in response to a request from an external device (e.g., a controller). For example, the control circuit 100 may store data in the memory cell array 300 or output data stored in the memory cell array 300 to the external device, by controlling the internal circuits in response to the request from the external device. Furthermore, when the control circuit 100 controls the memory cell array 300 including memory cells that are sensitive to a temperature, the control circuit 100 may change a method of controlling the memory cell array 300 depending on the temperature. For example, after the start of a read operation, the control circuit 100 may control the read voltage generation circuit 200 so that the level of a read voltage Vread that is provided to the memory cell array 300 is changed depending on a temperature change. In an embodiment, the control circuit 100 may generate a voltage control signal V_c that controls the read voltage generation circuit 200, based on an on-temperature code on_code that is received from the temperature sensor 500 and an off-temperature code off_code that is received from the off-temperature determination circuit 600. In this case, the read operation may be an operation of outputting data stored in the memory cell array 300 to the external device.

The read voltage generation circuit 200 may generate the read voltage Vread that is provided to the memory cell array 300, based on the voltage control signal V_c that is received from the control circuit 100. For example, the read voltage generation circuit 200 may change the level of the read voltage Vread based on the voltage control signal V_c.

The memory cell array 300 may include a plurality of memory cells (not illustrated). In this case, the memory cell may be a component that stores data. The memory cell may be made of a chalcogenide-series material. The level of the threshold voltage of the memory cell may be changed based on the direction of a current that penetrates the memory cell. For example, when the direction of the current that penetrates the memory cell is a first direction, the memory cell may switch to a first state. When the direction of the current that penetrates the memory cell is a second direction, the memory cell may switch to a second state. In this case, the threshold voltage of the memory cell in the first state may be different from the threshold voltage of the memory cell in the second state. Furthermore, the first direction and the second direction in which the current penetrates the memory cell may be different directions.

Furthermore, the memory cell array 300 may include a specific region 310 including at least one memory cell that is not used to store data that are received from the external device. In other words, the specific region 310 may be a region in the memory cell array 300 other than one or more regions in the memory cell array 300 designated to store data received from an external device. The memory cell array 300 that is included in the memory device according to an embodiment of the present disclosure may include the specific region 310 including at least one memory cell that is constructed so that the at least one memory cell switches to the first state (e.g., a set state) when power of the memory device becomes off.

After the start of a read operation, the data output circuit 400 may detect and determine the state of each of memory cells of the memory cell array 300 and output the state as data DATA. For example, when detecting and determining that the state of a memory cell is the first state (or the set state), the data output circuit 400 may output the data DATA being at a first level. Furthermore, when detecting and determining that the state of a memory cell is a second state (or a reset state), the data output circuit 400 may output the data DATA being at a second level. In this case, the first level and the second level may be different levels.

The temperature sensor 500 may sense a current temperature, and may generate the on-temperature code on_code having a code value based on the sensed temperature. In an embodiment, the temperature sensor 500 may sense a current temperature of the memory device 1 of FIG. 1. For example, the temperature sensor 500 may sense a current temperature of one or more memory cells in the memory array 300. The temperature sensor 500 may provide the on-temperature code on_code to the control circuit 100.

The off-temperature determination circuit 600 may generate the off-temperature code off_code by detecting the threshold voltage V_mth of at least one memory cell that is included in the specific region 310. The off-temperature determination circuit 600 may provide the off-temperature code off_code to the control circuit 100. For example, the off-temperature determination circuit 600 may generate the off-temperature code off_code having a code value corresponding to the level of the threshold voltage V_mth of a memory cell included in the specific region 310, and may provide the off-temperature code off_code to the control circuit 100.

In this case, the control circuit 100 may change the level of the read voltage Vread based on the off-temperature code off_code for a given time interval (e.g., a set time interval or a preset time interval) after power is applied to the memory device in the power off state, that is, after the memory device switches to the power on state. For example, the preset time interval may be determined based on a period during which the temperature sensor 500 is stabilized to output a precise temperature of one or more memory cells in the memory cell array 300, thereby ensuring reliable read operations on the memory cells. Furthermore, after the set time interval elapses, the control circuit 100 may change the level of the read voltage Vread based on the on-temperature code on_code. In an embodiment of the present disclosure, the construction of the memory device that changes the level of the read voltage Vread based on the off-temperature code off_code and the on-temperature code on_code is described. However, it is to be noted that the off-temperature code off_code and the on-temperature code on_code may also be applied to various operations of a memory device that needs to be controlled depending on a temperature change.

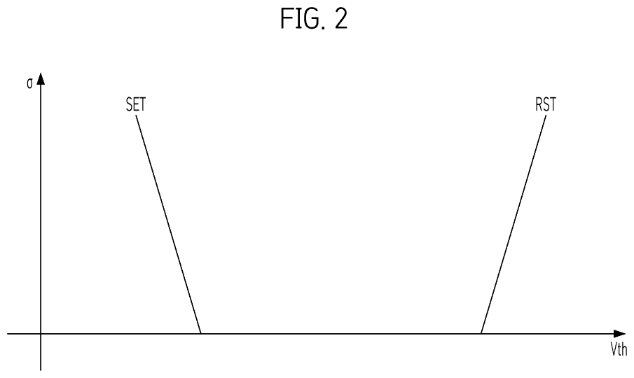

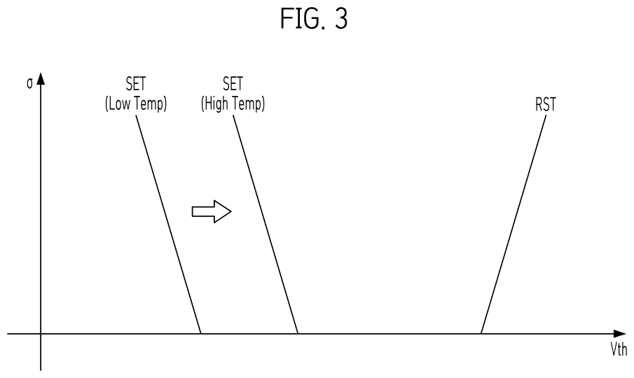

FIGS. 2 and 3 are diagrams for describing memory cells of the memory device according to an embodiment of the present disclosure.

FIG. 2 is a diagram for describing that the threshold voltage of a memory cell is changed by a write operation. In this case, the write operation may be an operation of the memory cell switching to the first state SET or the second state RST.

Referring to FIG. 2, each of the plurality of memory cells included in the memory cell array 300 may switch to the first state SET or the second state RST. In an embodiment, the memory cell array 300 may include a plurality of memory cells that is electrically connected between a bit line and a word line. In this case, when a current flows from the bit line to the word line through a memory cell, the memory cell may switch to the first state (e.g., the set state SET). When a current flows from the word line to the bit line through a memory cell, the memory cell may switch to the second state (e.g., the reset state RST). The threshold voltage of the memory cell in the second state RST may have a higher level than the threshold voltage of the memory cell in the first state SET. Furthermore, the memory cell array 300 may be constructed so that a current flows from a word line to a bit line through a memory cell after the start of a read operation. In this case, when the current flows from the bit line to the word line through the memory cell, the direction of the current that penetrates the memory cell may be defined as a first direction. Furthermore, when the current flows from the word line to the bit line through the memory cell, the direction of the current that penetrates the memory cell may be defined as a second direction.

FIG. 3 is a diagram for describing a memory cell the level of the threshold voltage of which is changed depending on a temperature.

Referring to FIG. 3, the level of the threshold voltage of a memory cell in the first state SET, among the plurality of memory cells that is included in the memory cell array 300, may be changed depending on a temperature. For example, the level of the threshold voltage Vth of the memory cell in the first state SET may be higher when a temperature is high (High Temp) than when the temperature is low (Low Temp), that is, as the temperature becomes high.

The read voltage Vread that is provided after the start of a read operation may be a voltage being at a level between the levels of the threshold voltage of a memory cell in the first state SET and the threshold voltage of a memory cell in the second state RST. For example, the read voltage Vread may be a voltage being at a center level of the threshold voltage of a memory cell in the first state SET and the threshold voltage of a memory cell in the second state RST, that is, an average level of the threshold voltages in the first and second states SET and RST.

Accordingly, when the level of the threshold voltage of a memory cell in the first state SET is changed depending on a temperature, the level of the read voltage Vread also needs to be changed.

The state of each of the memory cells of the memory cell array 300 that is included in the memory device according to an embodiment of the present disclosure may be switched due to a write operation. The level of the threshold voltage of a memory cell in the first state may be changed depending on a temperature. Furthermore, the state of a memory cell may be maintained after the memory cell has been switched due to a write operation, even when power applied to the memory device is off because the memory cell may have non-volatile memory characteristics.

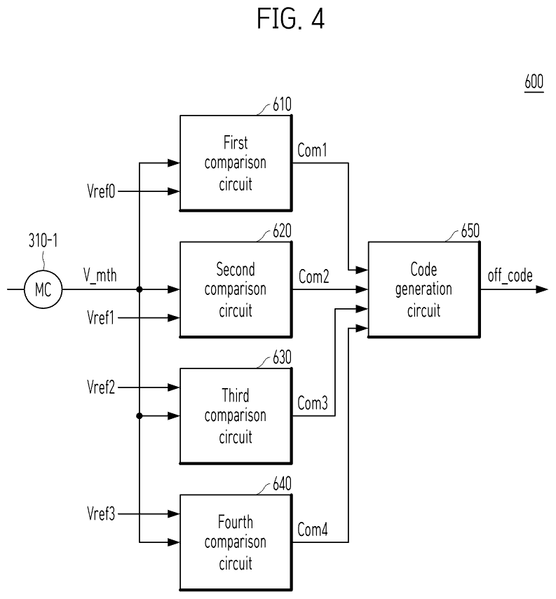

FIG. 4 is a diagram for describing a construction of the off-temperature determination circuit 600 according to an embodiment of the present disclosure. In this case, when power is provided to the memory device in the power off state, the read voltage generation circuit 200 may provide the read voltage Vread being at a given level (e.g., a set level) to a memory cell (MC) 310-1 included in the specific region 310 of the memory cell array 300. When the read voltage Vread being at the set level is provided to the memory cell 310-1 of the specific region 310, a voltage corresponding to the threshold voltage V_mth of the memory cell 310-1 may be provided to the off-temperature determination circuit 600. The voltage corresponding to the threshold voltage V_mth of the memory cell 310-1, which is provided to the off-temperature determination circuit 600, may have a different level depending on a temperature as illustrated in FIG. 3.

Furthermore, the off-temperature determination circuit according to an embodiment of the present disclosure may be constructed to determine the level of change of the threshold voltage V_mth of the memory cell 310-1 based on intervals implemented by a plurality of comparison circuits that receives reference voltages being at different levels. The off-temperature determination circuit may be further implemented to generate the off-temperature code off_code corresponding to the determined level of change of the threshold voltage V_mth. Although FIG. 4 illustrates that the off-temperature determination circuit 600 includes first to fourth comparison circuits 610, 620, 630, and 640 as an embodiment, the number of comparison circuits may vary according to embodiments of the present disclosure. The off-temperature determination circuit 600 may be constructed by increasing or decreasing the number of comparison circuits, if desirable.

Referring to FIG. 4, the off-temperature determination circuit 600 may generate the off-temperature code off_code based on the level of the threshold voltage V_mth of at least one memory cell 310-1 included in the specific region 310. In this case, the at least one memory cell 310-1 included in the specific region 310 may switch to a predetermined state, that is, the first state SET, when power applied to the memory device becomes off. That is, a write operation of a memory cell switching to the first state SET may be performed on the at least one memory cell 310-1 included in the specific region 310 when the power applied to the memory device becomes off. Thereafter, when power is applied to the memory device, the off-temperature determination circuit 600 may generate the off-temperature code off_code by detecting the level of the threshold voltage V_mth of the at least one memory cell 310-1 included in the specific region 310. The off-temperature code off_code that is generated by the off-temperature determination circuit 600 may be provided to the control circuit 100.

In an embodiment, the off-temperature determination circuit 600 may include the first to fourth comparison circuits 610, 620, 630, and 640 and a code generation circuit 650.

The first comparison circuit 610 may generate a first comparison signal Com1 by comparing the levels of a voltage corresponding to the threshold voltage V_mth of the memory cell 310-1 included in the specific region 310 and a first reference voltage Vref0. For example, the first comparison circuit 610 may change the level of the first comparison signal Com1 by comparing the levels of the voltage corresponding to the threshold voltage V_mth of the memory cell 310-1 and the first reference voltage Vref0. In an embodiment, when the level of the voltage corresponding to the threshold voltage V_mth of the memory cell 310-1 is lower than the level of the first reference voltage Vref0, the first comparison circuit 610 may generate the first comparison signal Com1 having a first value (e.g., a low level). When the level of the voltage corresponding to the threshold voltage V_mth of the memory cell 310-1 is higher than the level of the first reference voltage Vref0, the first comparison circuit 610 may generate the first comparison signal Com1 having a second value (e.g., a high level).

The second comparison circuit 620 may generate a second comparison signal Com2 by comparing the levels of the voltage corresponding to the threshold voltage V_mth of the memory cell 310-1 included in the specific region 310 and a second reference voltage Vref1. For example, the second comparison circuit 620 may change the level of the second comparison signal Com2 by comparing the levels of the voltage corresponding to the threshold voltage V_mth of the memory cell 310-1 and the second reference voltage Vref1. In an embodiment, when the level of the voltage corresponding to the threshold voltage V_mth of the memory cell 310-1 is lower than the level of the second reference voltage Vref1, the second comparison circuit 620 may generate the second comparison signal Com2 having a first value (e.g., a low level). In contrast, when the level of the voltage corresponding to the threshold voltage V_mth of the memory cell 310-1 is higher than the level of the second reference voltage Vref1, the second comparison circuit 620 may generate the second comparison signal Com2 having a second value (e.g., a high level).

The third comparison circuit 630 may generate a third comparison signal Com3 by comparing the levels of the voltage corresponding to the threshold voltage V_mth of the memory cell 310-1 included in the specific region 310 and a third reference voltage Vref2. For example, the third comparison circuit 630 may change the level of the third comparison signal Com3 by comparing the levels of the voltage corresponding to the threshold voltage V_mth of the memory cell 310-1 and the third reference voltage Vref2. In an embodiment, when the level of the voltage corresponding to the threshold voltage V_mth of the memory cell 310-1 is lower than the level of the third reference voltage Vref2, the third comparison circuit 630 may generate the third comparison signal Com3 having a first value (e.g., a low level). In contrast, when the level of the voltage corresponding to the threshold voltage V_mth of the memory cell 310-1 is higher than the level of the third reference voltage Vref2, the third comparison circuit 630 may generate the third comparison signal Com3 having a second value (e.g., a high level).

The fourth comparison circuit 640 may generate a fourth comparison signal Com4 by comparing the levels of the voltage corresponding to the threshold voltage V_mth of the memory cell 310-1 included in the specific region 310 and a fourth reference voltage Vref3. For example, the fourth comparison circuit 640 may change the level of the fourth comparison signal Com4 by comparing the levels of the voltage corresponding to the threshold voltage V_mth of the memory cell 310-1 and the fourth reference voltage Vref3. In an embodiment, when the level of the voltage corresponding to the threshold voltage V_mth of the memory cell 310-1 is lower than the level of the fourth reference voltage Vref4, the fourth comparison circuit 640 may generate the fourth comparison signal Com4 having a first value (e.g., a low level). In contrast, when the level of the voltage corresponding to the threshold voltage V_mth of the memory cell 310-1 is higher than the level of the fourth reference voltage Vref3, the fourth comparison circuit 640 may generate the fourth comparison signal Com3 having a second value (e.g., a high level). In this case, the levels of the first to fourth reference voltages Vref0, Vref1, Vref2, and Vref3 may be different. Furthermore, the level may be increased in the order of the first reference voltage Vref0, the second reference voltage Vref1, the third reference voltage Vref2, and the fourth reference voltage Vref3.

The code generation circuit 650 may generate the off-temperature code off_code based on the first to fourth comparison signals Com1, Com2, Com3, and Com4. The first to fourth comparison signals Com1, Com2, Com3, and Com4 indicate comparison results output from the first to fourth comparison circuits 610 to 640, respectively.

For example, when the level of a voltage corresponding to the level of the threshold voltage V_mth of the memory cell 310-1 included in the specific region 310 is lower than the level of the first reference voltage Vref0, the levels of all of the first to fourth comparison signals Com1, Com2, Com3, and Com4 may be a low level.

When all of the first to fourth comparison signals Com1, Com2, Com3, and Com4 are at a low level, that is, the level of the voltage corresponding to the threshold voltage V_mth is lower than the level of the first reference voltage Vref0, the code generation circuit 650 may generate the off-temperature code off_code having the lowest code value.

When the level of the voltage corresponding to the level of the threshold voltage V_mth of the memory cell 310-1 included in the specific region 310 is a level between the levels of the first reference voltage Vref0 and the second reference voltage Vref1, only the level of the first comparison signal Com1, among the first to fourth comparison signals Com1, Com2, Com3, and Com4, may be a high level, and the levels of the second to fourth comparison signals Com2, Com3, and Com4 may be a low level.

When the level of the first comparison signal Com1, among the first to fourth comparison signals Com1, Com2, Com3, and Com4, is high level, that is, the level of the voltage corresponding to the threshold voltage V_mth is between the levels of the first reference voltage Vref0 and the second reference voltage Vref1, the code generation circuit 650 may generate the off-temperature code off_code having the second lowest code value.

When the level of the voltage corresponding to the level of the threshold voltage V_mth of the memory cell 310-1 included in the specific region 310 is between the levels of the second reference voltage Vref1 and the third reference voltage Vref2, only the levels of the first and second comparison signals Com1 and Com2, among the first to fourth comparison signals Com1, Com2, Com3, and Com4, may be a high level, and the levels of the third and fourth comparison signals Com3 and Com4 may be a low level.

When only the levels of the first and second comparison signals Com1 and Com2, among the first to fourth comparison signals Com1, Com2, Com3, and Com4, are a high level, that is, the level of the voltage corresponding to the threshold voltage V_mth is between the levels of the second reference voltage Vref1 and the third reference voltage Vref2, the code generation circuit 650 may generate the off-temperature code off_code having the third lowest code value.

When the level of the voltage corresponding to the level of the threshold voltage V_mth of the memory cell 310-1 included in the specific region 310 is between the levels of the third reference voltage Vref2 and the fourth reference voltage Vref3, the levels of the first to third comparison signals Com1, Com2, and Com3, among the first to fourth comparison signals Com1, Com2, Com3, and Com4, may be a high level, and the level of the fourth comparison signal Com4 may be a low level.

When only the levels of the first to third comparison signals Com1, Com2, and Com3, among the first to fourth comparison signals Com1, Com2, Com3, and Com4, are a high level, that is, the level of the voltage corresponding to the threshold voltage V_mth is between the levels of the third reference voltage Vref2 and the fourth reference voltage Vref3, the code generation circuit 650 may generate the off-temperature code off_code having the fourth lowest code value.

When the level of the voltage corresponding to the level of the threshold voltage V_mth of the memory cell 310-1 included in the specific region 310 is higher than the level of the fourth reference voltage Vref3, the levels of all of the first to fourth comparison signals Com1, Com2, Com3, and Com4 may be a high level.

When the levels of all of the first to fourth comparison signals Com1, Com2, Com3, and Com4 are a high level, that is, the level of the voltage corresponding to the threshold voltage V_mth of the memory cell is higher than the level of the fourth reference voltage Vref3, the code generation circuit 650 may generate the off-temperature code off_code having the highest code value.

As described above, the first to fourth comparison circuits 610, 620, 630, and 640 illustrated in FIG. 4 may each be constructed to determine the level of the threshold voltage V_mth of the memory cell, which is included in any one of a first interval in which the level of the threshold voltage V_mth is lower than the level of the first reference voltage Vref0, a second interval in which the level of the threshold voltage V_mth is between the levels of the first reference voltage Vref0 and the second reference voltage Vref1, a third interval in which the level of the threshold voltage V_mth is between the levels of the second reference voltage Vref1 and the third reference voltage Vref2, a fourth interval in which the level of the threshold voltage V_mth is between the levels of the third reference voltage Vref2 and the fourth reference voltage Vref3, and a fifth interval in which the level of the threshold voltage V_mth is higher than the level of the fourth reference voltage Vref3, by receiving the first to fourth reference voltages Vref0, Vref1, Vref2, and Vref3, respectively. Although the off-temperature determination circuit 600 according to the embodiment of FIG. 4 is implemented using four reference voltages and four comparison circuits to determine a level of change of the threshold voltage V_mth of the memory cell 310-1 based on five intervals, the number of reference voltages and the number of comparison circuits may vary to change the number of intervals according to embodiments of the present disclosure. For example, an off-temperature determination circuit according to an embodiment that increases the number of reference voltages being at different levels and the number of comparison circuits may be changed and implemented to increase the number of intervals. In contrast, an off-temperature determination circuit according to an embodiment that decreases the number of reference voltages being at different levels and the number of comparison circuits may be changed and implemented to decrease the number of intervals.

Furthermore, an interval which may be determined by the off-temperature determination circuit 600 may be reduced, if necessary, by deactivating one or more of the first to fourth comparison circuits 610, 620, 630, and 640. For example, when the first comparison circuit 610, among the first to fourth comparison circuits 610, 620, 630, and 640, is deactivated, the off-temperature determination circuit 600 may be constructed to determine the level of the threshold voltage V_mth of the memory cell, which is included in any one of an interval in which the level of the threshold voltage V_mth is lower than the level of the second reference voltage Vref1, an interval in which the level of the threshold voltage V_mth is between the levels of the second and third reference voltages Vref1 and Vref2, an interval in which the level of the threshold voltage V_mth is between the levels of the third and fourth reference voltages Vref2 and Vref3, and an interval in which the level of the threshold voltage V_mth is higher than the level of the fourth reference voltage Vref3. That is, when the first comparison circuit 610, among the first to fourth comparison circuits 610, 620, 630, and 640, is deactivated, the off-temperature determination circuit 600 may be constructed to determine one interval including the level of the threshold voltage V_mth, among the four intervals. Accordingly, the off-temperature determination circuit including a plurality of comparison circuits may be constructed to adjust the number of intervals in which the level of the threshold voltage V_mth will be determined, by deactivating one or more of the plurality of comparison circuits.

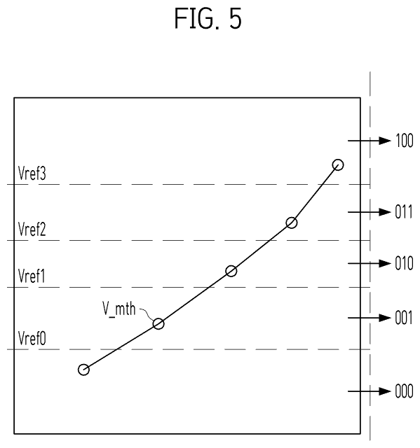

FIG. 5 is a diagram for describing an operation of an off-temperature determination circuit (e.g., the off-temperature determination circuit 600 in FIG. 4) according to an embodiment of the present disclosure. In this case, a voltage corresponding to the threshold voltage V_mth of the memory cell 310-1 included in the specific region 310 is named the threshold voltage V_mth of the memory cell 310-1, for convenience of description. Furthermore, the off-temperature code off_code is described as having a 3-bit code value, but embodiments of the present disclosure are not limited thereto.

Referring to FIG. 5, the off-temperature determination circuit 600 according to an embodiment of the present disclosure may generate the off-temperature code off_code having the lowest code value, that is, a code value (0, 0, 0), when the level of the threshold voltage V_mth of the memory cell 310-1 included in the specific region 310 is lower than the level of the first reference voltage Vref0.

The off-temperature determination circuit 600 may generate the off-temperature code off_code having a code value (0, 0, 1), when the level of the threshold voltage V_mth of the memory cell 310-1 between the levels of the first and second reference voltages Vref0 and Vref1.

The off-temperature determination circuit 600 may generate the off-temperature code off_code having a code value (0, 1, 0), when the level of the threshold voltage V_mth of the memory cell 310-1 is between the levels of the second and third reference voltages Vref1 and Vref2.

The off-temperature determination circuit 600 may generate the off-temperature code off_code having a code value (0, 1, 1), when the level of the threshold voltage V_mth of the memory cell 310-1 is between the levels of the third and fourth reference voltages Vref2 and Vref3.

The off-temperature determination circuit 600 may generate the off-temperature code off_code having a code value (1, 0, 0), when the level of the threshold voltage V_mth of the memory cell 310-1 is higher than the level of the fourth reference voltage Vref3.

As a result, the off-temperature determination circuit 600 may generate the off-temperature code off_code having a code value according to variation in the threshold voltage of the memory cell 310-1 included in the specific region.

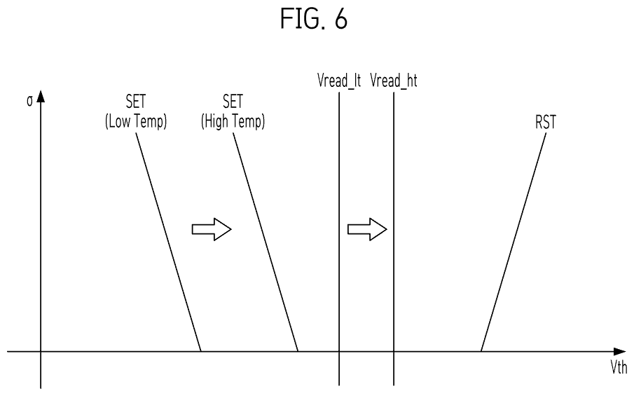

FIG. 6 is a graph for describing an operation of a memory device (e.g., the memory device 1 in FIG. 1) according to an embodiment of the present disclosure.

When power is provided to the memory device in the power off state, the control circuit 100 may control the read voltage generation circuit 200 and the memory cell array 300 so that the read voltage Vread being at a set level is provided to the memory cell 310-1 included in the specific region 310 of the memory cell array 300.

The off-temperature determination circuit 600 may generate the off-temperature code off_code having a code value changed based on the level of the threshold voltage V_mth that is provided by the memory cell 310-1 included in the specific region 310.

When power is applied to the memory cell 310-1 in the power off state, the control circuit 100 may change the level of the read voltage Vread based on a code value of the off-temperature off temperature code off_code for a set time interval.

Referring to FIG. 6, the level of the threshold voltage V_mth of the memory cell 310-1 included in the specific region 310, that is, the memory cell 310-1 in the first state SET, may be changed depending on a temperature change in the power off state. For example, the level of the threshold voltage V_mth of the memory cell 310-1 in the first state SET may be higher when a temperature is high (High Temp) than when a temperature is low (Low Temp).

Therefore, the off-temperature determination circuit 600 of the memory device according to an embodiment of the present disclosure may generate a temperature change that was experienced by the memory device in the power off state, as the off-temperature code off_code, based on the level of the threshold voltage of a memory cell included in the specific region 310. In other words, the off-temperature determination circuit 600 may generate the off-temperature code off_code indicating a temperature change occurred in the memory device in the power off state, based on the level of the threshold voltage of a memory cell included in the specific region 310.

In this case, the level of the threshold voltage of each of memory cells in the first state SET, among the plurality of memory cells included in the memory cell array 300, may also be changed depending on a temperature change. As in the memory cell 310-1 of the specific region 310, the level of the threshold voltage of each of the memory cells in the first state SET, which are included in the memory cell array 300, may be higher when a temperature is high (High Temp) than when the temperature is low (Low Temp). For example, a temperature change in the memory cell 310-1 included in the specific region 310 of the memory cell array 300 may represent a temperature change in one or more memory cells in another region of the memory cell array 300 designated to store data received from an external device.

When the memory device in the power off state is powered on, the memory device may change the level of the read voltage Vread based on the off-temperature code off_code. In this case, the memory device may provide the memory cell array 300 with the read voltage Vread being at a higher level when the memory device in the power off state experienced a high temperature (High Temp) than when the memory device in the power off state experienced a low temperature (Low Temp), based on the off-temperature code off_code. FIG. 6 illustrates, as Vread_lt, the read voltage Vread when the memory device in the power off state experienced the low temperature (Low Temp), and illustrates, as Vread_ht, when the memory device in the power off state experienced the high temperature (High Temp).

As a result, when the memory device in the power off state according to an embodiment of the present disclosure is powered on, the memory device may generate the read voltage Vread based on the off-temperature code off_code for a set time interval (e.g., a preset time interval) and provide the read voltage Vread to the memory cell array 300 after the start of a read operation, thereby improving the reliability of data storage in the memory device.

In other words, when the memory device in the power off state according to an embodiment of the present disclosure is powered on, the memory device may change the level of a read voltage based on variation in the threshold voltage of a memory cell included in a specific region for a set time interval, and may provide the read voltage to the memory cell array 300 after the start of a read operation.

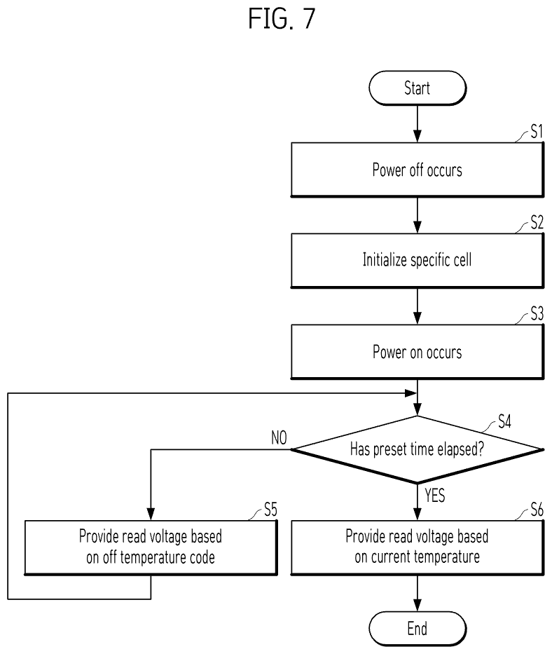

FIG. 7 is a flowchart for describing an operation of a memory device (e.g., the memory device 1 of FIG. 1) according to an embodiment of the present disclosure.

Referring to FIG. 7, the operating method of the memory device according to an embodiment of the present disclosure may include a power-off occurrence process S1, a specific cell initialization process S2, a power-on occurrence process S3, a time elapse determination process S4, a first read voltage provision process S5, and a second read voltage provision process S6.

The power-off occurrence process S1 may include cutting off power applied to the memory device. For example, the power applied to the memory device may be cut off intentionally, or by accident. In an embodiment, the power-off occurrence process S1 may include detecting an occurrence of power off (intentional or by accident) to a memory device.

The specific cell initialization process S2 may include writing at least one memory cell (e.g., the memory cell 310-1 included in the specific region 310 of the memory cell array 300) in a predetermined state (e.g., the first state SET), during the power-off occurrence process S1. For example, in the specific cell initialization process S2, the memory device may perform a writing operation on the memory cell 310-1 included in the specific region 310 to make the memory cell 310-1 have a predetermined state (e.g., the first state SET), when the power applied to the memory device is cut off.

The power-on occurrence process S3 may include providing power to the memory device. In an embodiment, the power-on occurrence process S3 may include providing a set voltage to the memory cell 310-1 in the first state SET, which is included in the specific region 310, and generating the off-temperature code off_code based on the level of the threshold voltage of the memory cell 310-1 in the first state SET.

The time elapse determination process S4 may include determining whether a preset time interval has elapsed after the power-on occurrence process S3. For example, the time elapse determination process S4 may include determining whether a preset time interval has elapsed after power is provided to switch the memory device from a power-off state to a power-on state.

For example, when it is determined that the preset time interval has not elapsed (NO) after the power-on occurrence process S3 in the time elapse determination process S4, the first read voltage provision process S5 may be performed.

When it is determined that the preset time interval has elapsed (YES) after the power-on occurrence process S3 in the time elapse determination process S4, the second read voltage provision process S6 may be performed.

The first read voltage execution process S5 may include providing the memory cell array 300 with the read voltage Vread based on the off-temperature code off_code after the start of a read operation. After the first read voltage execution process S5 is completed, the time elapse determination process S4 may be performed again. Accordingly, if the preset time interval has not elapsed after the power on occurrence process S3, the first read voltage execution process S5 may be a process that is performed whenever a read operation is performed.

The second read voltage execution process S6 may include a process of providing the memory cell array 300 with the read voltage Vread based on a current temperature. In this case, the second read voltage execution process S6 may include a process of the control circuit 100 controlling the read voltage generation circuit 200 based on the on-temperature code on_code that is provided by the temperature sensor 500. As a result, the read voltage generation circuit 200 generates the read voltage Vread that is provided to the memory cell array 300 whenever a read operation is performed.

In an embodiment, an operating method of a memory device including a memory cell array comprises: generating an off-temperature code based on a characteristic of at least one memory cell in a specific region of the memory cell array, the off-temperature code indicating a temperature change occurred in the memory device in a power off state; and generating a read voltage based on the off-temperature code to provide the read voltage to the memory cell array. For example, the characteristic of the at least one memory cell may be a threshold voltage thereof.

In an embodiment, the method further comprises writing the at least one memory cell to have a predetermined state when power of the memory device is cut off.

In an embodiment, the method further comprises applying the power to the memory device. The read voltage is generated based on a level of a threshold voltage of the at least one memory cell after the power is applied to the memory device.

In an embodiment, the predetermined state of the at least one memory cell is a set state.

In an embodiment, applying the power comprises providing the read voltage having a given level to the at least one memory cell in the set state. The off-temperature code is generated based on a level of the threshold voltage of the at least one memory cell.

In an embodiment, generating the read voltage comprises providing the read voltage to the memory cell array based on the off-temperature code for a preset time interval after the power is applied to the memory device.

In an embodiment, generating the read voltage further comprises providing the read voltage to the memory cell array based on an on-temperature code of a temperature sensor after the preset time interval elapses.

In an embodiment, generating the off-temperature code comprises comparing a level of each of a plurality of reference voltages having different levels and the level of the threshold voltage of the at least one memory cell.

Although some embodiments of the present disclosure have been described above with reference to the accompanying drawings, embodiments of the present disclosure are not limited to the above-described embodiments. A person having ordinary knowledge in the art to which the present disclosure pertains may substitute, modify, and change the embodiments in various ways. Such substitutions, modifications, and changes may belong to the scope of various embodiments of the present disclosure.

What is claimed is:

1. A memory device comprising:
a memory cell array comprising a plurality of memory cells;
an off-temperature determination circuit configured to generate an off-temperature code based on a level of a threshold voltage of at least one memory cell included in a specific region of the memory cell array;
a control circuit configured to generate a voltage control signal based on the off-temperature code; and
a read voltage generation circuit configured to provide a read voltage to the memory cell array based on the voltage control signal.

2. The memory device of claim 1, wherein the memory device performs a writing operation on the at least one memory cell to have a predetermined state when power applied to the memory device is cut off.

3. The memory device of claim 2, wherein the off-temperature determination circuit generates the off-temperature code having a code value based on a level of change of the threshold voltage of the at least one memory cell.

4. The memory device of claim 3, wherein the control circuit generates the voltage control signal based on the off-temperature code so that a level of the read voltage is changed based on the level of change of the threshold voltage of the at least one memory cell.

5. The memory device of claim 1, wherein:
the plurality of memory cells include the at least one memory cell included in the specific region;
each of the plurality of memory cells is configured to switch to a first state or a second state; and
a first level of a first threshold voltage of each of the plurality of memory cells in the first state is lower than a second level of a second threshold voltage of each of the plurality of memory cells in the second state.

6. The memory device of claim 5, wherein the at least one memory cell included in the specific region switches to the first state when power applied to the memory device is cut off.

7. The memory device of claim 6, wherein the control circuit generates the voltage control signal based on the off-temperature code so that a level of the read voltage increases as that of the first threshold voltage of the at least one memory cell in the first state increases.

8. The memory device of claim 1, further comprising a temperature sensor configured to generate an on-temperature code based on a change of a current temperature of the memory device.

9. The memory device of claim 8, wherein the control circuit generates the read voltage based on the off-temperature code for a preset time interval after power is provided to the memory device, and generates the read voltage based on the on-temperature code when the preset time interval elapses.

10. The memory device of claim 1, wherein:
the off-temperature determination circuit comprises a plurality of comparison circuits; and
the plurality of comparison circuits receive a plurality of reference voltages having a plurality of different levels, respectively, and each of the plurality of comparison circuits compares a level of the threshold voltage of the at least one memory cell and a level of a corresponding one of the plurality of reference voltages.

11. The memory device of claim 10, wherein the off-temperature determination circuit further comprises a code generation circuit configured to generate the off-temperature code based on comparison results that are output from the plurality of comparison circuits.

12. The memory device of claim 11, wherein the code generation circuit generates the off-temperature code having a code value that increases as the level of the threshold voltage of the at least one memory cell increases.

13. An operating method of a memory device including a memory cell array, comprising:
generating an off-temperature code based on a characteristic of at least one memory cell in a specific region of the memory cell array, the off-temperature code indicating a temperature change occurred in the memory device in a power off state; and
generating a read voltage based on the off-temperature code to provide the read voltage to the memory cell array.

14. The operating method of claim 13, further comprising writing the at least one memory cell to have a predetermined state when power of the memory device is cut off.

15. The operating method of claim 14, further comprising applying the power to the memory device,
wherein the read voltage is generated based on a level of a threshold voltage of the at least one memory cell after the power is applied to the memory device.

16. The operating method of claim 15, wherein the predetermined state of the at least one memory cell is a set state.

17. The operating method of claim 16, wherein applying the power comprises providing the read voltage having a given level to the at least one memory cell in the set state, and
wherein the off-temperature code is generated based on the level of the threshold voltage of the at least one memory cell.

18. The operating method of claim 17, wherein generating the read voltage comprises providing the read voltage to the memory cell array based on the off-temperature code for a preset time interval after the power is applied to the memory device.

19. The operating method of claim 18, wherein generating the read voltage further comprises providing the read voltage to the memory cell array based on an on-temperature code of a temperature sensor after the preset time interval elapses.

20. The operating method of claim 17, wherein generating the off-temperature code comprises comparing a level of each of a plurality of reference voltages having different levels and the level of the threshold voltage of the at least one memory cell.

21. The operating method of claim 20, wherein the generating the off-temperature code comprises generating the off-temperature code based on an interval corresponding to the threshold voltage of the at least one memory cell, among intervals to which the plurality of reference voltages belongs.

22. An operating method of a memory device, comprising:
cutting off power to a memory device; and
writing a specific cell in a predetermined state when the power of the memory device is cut off.
